(19) United States
(12) Patent Application Publication
(10) Pub. No.: US 2013/0147560 A1
(43) Pub. Date: Jun. 13, 2013

(54) LOW NOISE AMPLIFIER WITH BACK-TO-BACK CONNECTED DIODES AND BACK-TO-BACK CONNECTED DIODE WITH HIGH IMPEDANCE THEREOF

(71) Applicants: Wei-Hsien CHEN, Hsinchu City (TW); Kuei-Cheng Lin, Hsinchu City (TW); Bing-Song Chen, Hsinchu City (TW); Chien-Chih Lin, Hsinchu City (TW)

(72) Inventors: Wei-Hsien CHEN, Hsinchu City (TW); Kuei-Cheng Lin, Hsinchu City (TW); Bing-Song Chen, Hsinchu City (TW); Chien-Chih Lin, Hsinchu City (TW)

(73) Assignee: National Chip Implementation Center National Applied Research Laboratories, Hsinchu City (TW)

(21) Appl. No.: 13/408,414

(22) Filed: Feb. 29, 2012

(30) Foreign Application Priority Data
Dec. 9, 2011 (TW) TW 100145437

(51) Int. Cl. H03F 3/45

(52) U.S. Cl. 330/260

(57) ABSTRACT

A low noise amplifier with back-to-back connected diodes and a back-to-back connected diode with high impedance thereof are provided. The low noise amplifier includes a first operational amplifier (OP) and at least two first back-to-back connected diodes. The back-to-back connected diode with high impedance is formed from at least one MOS FET operated within a cut-off region. The first back-to-back connected diodes are connected electrically between the first input end and the first output end, and between the second input end and the second output end, of the first OP respectively. By the implementation of the present invention, the low noise amplifier is not only low noise, but also with low energy consumption, high stability, low circuitry complexity, and easily controlled manufacturing process.

### BACKGROUND OF THE INVENTION

1. Technical Field

The present invention relates to low noise amplifiers with back-to-back connected diodes and back-to-back connected diodes with high impedance thereof, and more particularly, to a low noise amplifier with back-to-back connected diodes and a back-to-back connected diode with high impedance thereof for use with a bioelectronic device.

2. Description of Related Art

US publication No. 2003/0155966 discloses a low-power, low-noise CMOS (complementary metal oxide semiconductor) amplifier and specifically discloses that MOS diodes (metal oxide semiconductor diodes) operating at a reverse bias voltage range to function as a resistor structure of high resistance. However, if a positive half-cycle voltage of an output signal increases to above 0.2V, the resistance of the high-resistance resistor structure formed from MOS diodes will decrease drastically and thus cannot stay high steadily.

U.S. Pat. No. 7,102,438 discloses an autozeroing floating-gate amplifier and specifically discloses a method of attaining a high-resistance resistor by means of the MOS gate oxide tunnel effect. However, the method requires controlling the thickness of the MOS gate oxide layer and thus is not applicable to a typical process.

U.S. Pat. No. 7,339,384 discloses a system and method for sensing capacitance change of a capacitive sensor and specifically discloses a method based on the MOS gate oxide tunnel effect and thus is confronted with problems related to gate oxide layer thickness and difficulty in a process. Furthermore, U.S. Pat. No. 7,339,384 discloses controlling a charge on a floating gate by means of a programming circuit and thereby controlling a high-pass corner. However, the drawbacks of the U.S. Pat. No. 7,339,384 are that the circuit in its entirety is intricate and thus difficult to be put in use.

U.S. Pat. No. 7,336,123 discloses a chopper amplifier circuit apparatus operated at a low voltage utilizing a switched operational amplifier and specifically discloses that low-frequency noise is eliminated by means of a chopper of the chopper amplifier circuit apparatus. However, the aforesaid disclosure is not applicable to weak signals. For example, during a biomedical test, an applied neural driving voltage is usually below 100 mV; however, a voltage of several hundred mV is generated as soon as a clock signal passes through a capacitor, thereby interfering with the measurement of neural signals. Furthermore, the technical solution “eliminating low-frequency noise by means of a chopper” disclosed in U.S. Pat. No. 7,336,123 does not work for noise of frequency lower than 1 Hz.

The aforesaid published application and issued patents reveal: according to the prior art, the stability of the resistance of the high-resistance resistor structure formed from MOS diodes is susceptible to a change of voltage; the technical requirements for attaining a high-resistance resistor by means of the MOS gate oxide tunnel effect are strict; and elimination of low-frequency noise by means of a chopper of a chopper amplifier circuit apparatus is hardly applicable to a biomedical test. Accordingly, it is imperative to attain a low noise amplifier applicable to a biomedical test and characterized by a high-resistance resistor steadily operated.

### BRIEF SUMMARY OF THE INVENTION

The present invention relates to a low noise amplifier with back-to-back connected diodes and a back-to-back connected diode with high impedance thereof The low noise amplifier with back-to-back connected diodes comprises a first operational amplifier (OP) and at least two first back-to-back connected diodes. The back-to-back connected diode with high impedance is formed from at least one MOS FET operated within a cut-off region. The objective of the present invention is to provide a low noise amplifier with back-to-back connected diodes which is characterized by low noise, low power consumption, high stability, a simple circuit, and a process that is easy to control.

The present invention provides a low noise amplifier with back-to-back connected diodes, comprising: a first operational amplifier having a first input end, a second input end, a first output end, and a second output end; and at least two first back-to-back connected diodes electrically connected between the first input end and the first output end, and electrically connected between the second input end and the second output end, respectively, wherein the first back-to-back connected diodes are each formed from at least one MOS FET each operated within a cut-off region.

The present invention also provides a back-to-back connected diode with high impedance, applicable to a low noise amplifier with back-to-back connected diodes, the back-to-back connected diode being formed from at least one MOS FET each operated within a cut-off region.

Implementation of the present invention at least involves inventive steps as follows:

1. a low noise amplifier with back-to-back connected diodes which features a simple circuitry and thus its manufacturing process is easy to control and apply; and

2. the resistance of a back-to-back connected diode structure formed from a MOS FET does not vary much with voltage, and thus the back-to-back connected diode structure consumes little power and is highly stable.

### BRIEF DESCRIPTION OF THE DRAWINGS

The structure as well as a preferred mode of use, further objects, and advantages of the present invention will be best understood by referring to the following detailed description of some illustrative embodiments in conjunction with the accompanying drawings, in which:

FIG. 1 is a circuit diagram of a low noise amplifier with back-to-back connected diodes according to an embodiment of the present invention;

FIG. 2 is a characteristic curve of a back-to-back connected diode according to an embodiment of the present invention;

FIG. 3A is a structural schematic view of a back-to-back connected diode formed from a PMOS FET according to an embodiment of the present invention;

FIG. 3B is a circuit structure diagram of a back-to-back connected diode formed from a PMOS FET according to an embodiment of the present invention;

FIG. 4A is a structural schematic view of a back-to-back connected diode formed from an NMOS FET according to an embodiment of the present invention;

FIG. 4B is a circuit structure diagram of a back-to-back connected diode formed from a PMOS FET according to an embodiment of the present invention; and

FIG. 5 is a -circuit diagram of a low noise amplifier with back-to-back connected diodes further comprising a second operational amplifier according to an embodiment of the present invention.

### DETAILED DESCRIPTION OF THE INVENTION

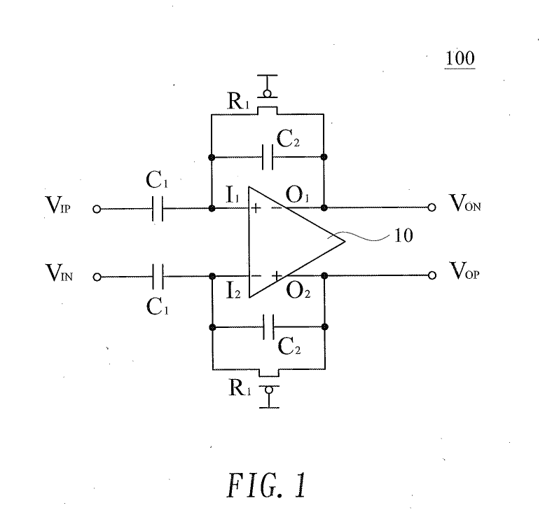

Referring to FIG. 1, in this embodiment, a low noise amplifier 100 with back-to-back connected -diodes includes a first operational amplifier (OP) 10 and at least two first back-to-back connected diodes R₁.

The first operational amplifier 10 has a first input end I₁, a second input end I₂, a first output end O₁, and a second output end O₂. The first input end I₁ functions as the positive terminal signal input end of the first operational amplifier 10. The second input end I₂ functions as the negative terminal signal input end of the first operational amplifier 10. The first input end I₁ and the second input end I₂ are series-connected to a first capacitor C₁, respectively, for filtering out a DC component of an input signal. The first output end O₁ functions as the negative terminal signal output end of the first operational amplifier 10. The second output end O₂ functions as the positive terminal signal output end of the first operational amplifier 10. One of two second capacitors C₂ is series-connected between the first input end I₁ and the first output end O₁, and the other one of the two second capacitors C₂ is series-connected between the second input end I₂ and the second output end O₂. The second capacitor C₂ filters out DC components of a feedback signal fed back from the first output end O₁ to the first input end I₁ and a feedback signal fed back from the second output end O₂ to the second input end I₂. Furthermore, the gain of the low noise amplifier 100 with back-to-back connected diodes equals C₁/C₂, that is, the ratio of the capacitance of the first capacitor C₁ to the capacitance of the second capacitor C₂. Therefore, the gain of the low noise amplifier 100 with back-to-back connected diodes can be adjusted as a result of a change in the ratio C₁/C₂, and a change in the ratio C₁/C₂ can be achieved by adjusting the capacitance of the first capacitor C₁ or adjusting the capacitance of the second capacitor C₂.

One of the two first back-to-back connected diodes R₁ is electrically connected between the first input end I₁ and the first output end O₁. The other one of the two first back-to-back connected diodes R₁ is electrically connected between the second input end I₂ and the second output end O₂. The first back-to-back connected diodes R₁ function as a feedback resistor between the first output end O₁ and the first input end I₁ and a feedback resistor between the second output end O₂ and the second input end I₂, respectively. Each of the first back-to-back connected diodes R₁ is formed from at least one MOS FET each operated within a cut-off region.

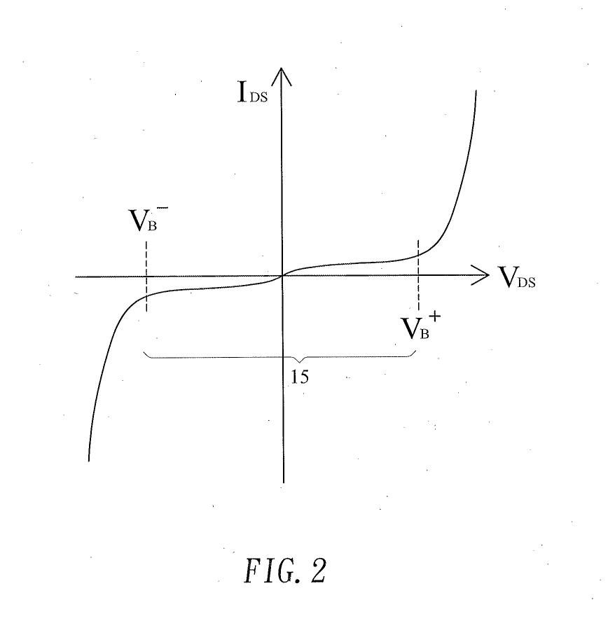

Referring to FIG. 2, in the situation where each of the first back-to-back connected diodes R₁ is formed from a MOS FET each operated within a cut-off region 15, and the current-voltage relation of the back-to-back connected diodes is depicted by a curve with the voltage greater than a reverse diode breakdown voltage VB but less than a forward diode breakdown voltage V_{B}⁺, the resistance of the first back-to-back connected diodes R₁ equals the ratio of voltage to current, that is; the reciprocal of the slope of a current vs. voltage graph; hence, the characteristic curve reveals: in the situation where the first back-to-back connected diodes R₁ are formed from the MOS FETs operated within the cut-off region 15, given the extremely small slope of the current vs. voltage graph within the cut-off region 15, the reciprocal of the slope is extremely large, thereby resulting in an extremely large resistance; furthermore, due to the flat slope of the current vs. voltage graph within the cut-off region 15, the variation of the slope is extremely small, thereby indicating an extremely small variation in the resistance of the first back-to-back connected diodes R₁ formed from the MOS FETs.

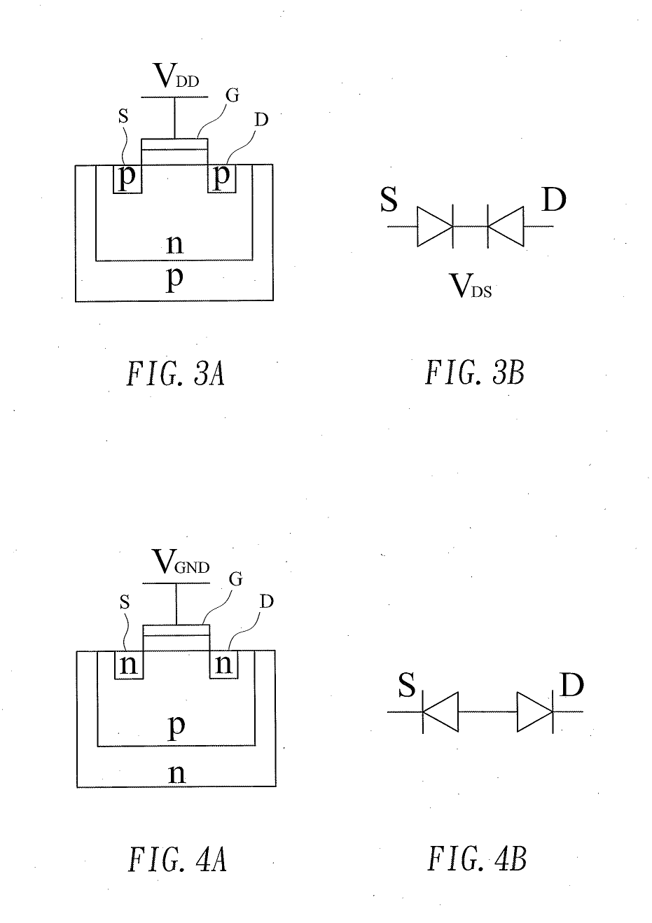

Referring to FIG. 3A and FIG. 3B, in this embodiment, different types of the MOS FETs can be selected and used, and thus the first back-to-back connected diodes R₁ can be arranged in two different ways to form different structures. In the first scenario, the drain D and the source S of at least one PMOS FET function as two P contacts of the first back-to-back connected diodes R₁ respectively to form a back-to-back P-N-N-P structure, and the gate G is connected to the highest voltage V_{DD} in a power supply circuit such that the back-to-back connected diodes of the back-to-back P-N-N-P structure operate within the cut-off region 15 and thus function as a high-resistance resistor. Not only is each of the first back-to-back connected diodes R₁ formed from one PMOS FET, but it is also feasible that each of the first back-to-back connected diodes R₁ comprises high-resistance resistors composed of a plurality of PMOS FETs and connected in series so as to provide higher resistance.

Referring to FIG. 4A and FIG. 4B, in the second scenario, the drain D and the source S of at least one NMOS FET function as two N contacts of the first back-to-back connected diodes R₁ respectively to form a back-to-back N-P-P-N structure, and the gate G is connected to the lowest voltage V_{GND} in a power supply circuit such that the back-to-back connected diodes of the N-P-P-N structure operate within the cut-off region 15 and thus function as a high-resistance resistor. Likewise, not only is each of the first back-to-back connected diodes R₁ formed from one NMOS FET, but it is also feasible that each of the first back-to-back connected diodes R₁ comprises high-resistance resistors composed of a plurality of NMOS FETs and connected in series so as to provide higher resistance.

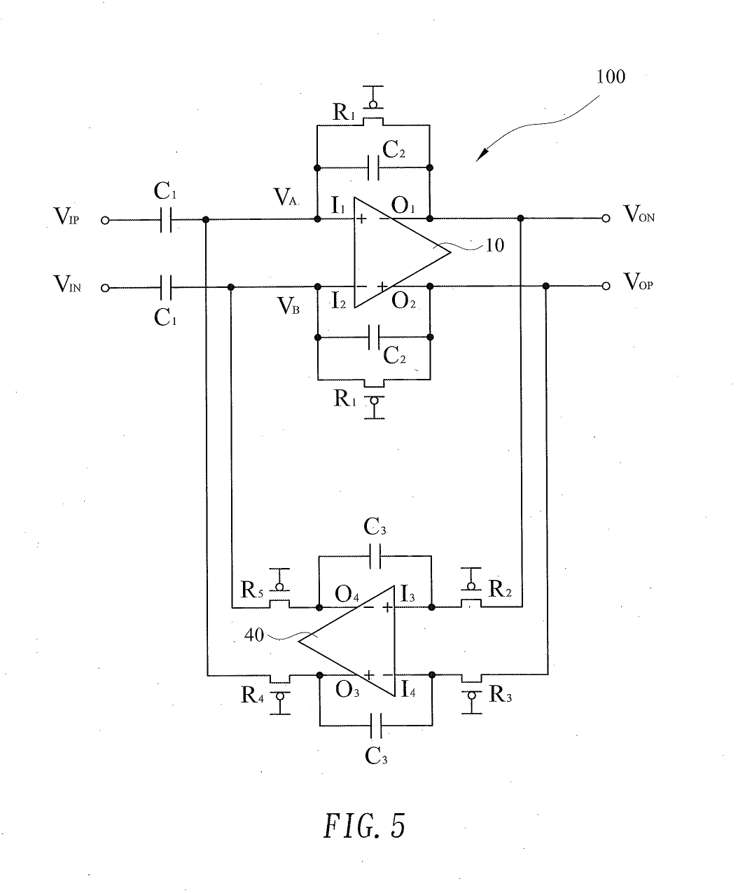

Referring to FIG. 5, in this embodiment, the low noise amplifier 100 with back-to-back connected diodes further comprises a second operational amplifier (OP) 40 which functions as a feedback amplifier for regulating the gain of the low noise amplifier 100 with back-to-back connected diodes. The second operational amplifier 40 has a third input end I₃, a fourth input end I₄, a third output end O₃, and a fourth output end O₄.

The third input end I₃ functions as the positive terminal signal input end of the second operational amplifier 40. A second back-to-back connected diode R₂ is series-connected between the third input end I₃ and the first output end O₁ for sending a signal from the first output end O₁ to the third input end I₃ via the second back-to-back connected diode R₂.

The fourth input end I₄ functions as the negative terminal signal input end of the second operational amplifier 40. A third back-to-back connected diode R₃ is series-connected to the fourth input end I₄ and the second output end O₂ for sending a signal from the second output end O₂ to the fourth input end I₄ via the third back-to-back connected diode R₃.

The third output end O₃ functions as the positive terminal signal output end of the second operational amplifier 40. A fourth back-to-back connected diode R₄ is series-connected between the third output end O₃ and the first input end I₁ for feeding back a signal from the third output end O₃ to the first input end I₁ of the first operational amplifier 10 via the fourth back-to-back connected diode R₄.

The fourth output end O₄ functions as the negative terminal signal output end of the second operational amplifier 40. A fifth back-to-back connected diode R₅ is series-connected between the fourth output end O₄ and the second input end I₂, such that a signal from the fourth output end O₄ can be fed back to the second input end I₂ of the first operational amplifier 10 via the fifth back-to-back connected diode R₅.

Furthermore, one of two third capacitors C is series-connected between the third input end I₃ and the fourth output end O₄, and the other one of the two third capacitors C₃ is series-connected between the fourth input end I₄ and the third output end O₃. The frequency at a high-pass corner of the low noise amplifier 100 with back-to-back connected diodes can be controlled. by adjusting the product of the resistance of the second back-to-back connected diode R₂ and the capacitance of the third capacitor C₃.

Furthermore, the ratio of the resistance of the first back-to-back connected diodes R₁ to the resistance of the fourth back-to-back connected diode R₄ equals the feedback gain. The extent of feedback can be adjusted by changing the resistance of the first back-to-back connected diodes R₁ and the resistance of the fourth back-to-back connected diode R₄, such that input end voltages V_{A}, V_{B} are stable. In addition, the feedback eliminates any DC offset which might otherwise occur to output end voltages V_{OP}, V_{ON}.

Like the first back-to-back connected diodes R₁, each of the second back-to-back connected diode R₂, the third back-to-back connected diode R₃, the fourth back-to-back connected diode R₄, and the fifth back-to-back connected diode R₅ can be formed from at least one MOS FET each operated within a cut-off region 15.

Being of the same structure as the first back-to-back connected diode R₁ is, each of the second back-to-back connected diode R₂, the third back-to-back connected diode R₃, the fourth back-to-back connected diode R₄, and the fifth back-to-back connected diode R₅ can be formed from at least one PMOS FET to thereby form a back-to-back connected diode structure of at least one P-N-N-P structure, or can be formed from at least one NMOS FET to thereby form a back-to-back connected diode structure of at least one N-P-P-N structure. From the perspective of formation, structure, and functionality, each of the second back-to-back connected diode R₂, the third back-to-back connected diode R₃, the fourth back-to-back connected diode R₄, and the fifth back-to-back connected diode R₅ is substantially identical to the first back-to-back connected diodes R₁ in terms of structure and thus are not described herein for the sake of brevity. Both the second back-to-back connected diode R₂ and the third back-to-back connected diode R₃ lie on the input side of the second operational amplifier 40, and thus it is necessary that the second back-to-back connected diode R₂ and the third back-to-back connected diode R₃ have the same structure characteristics. Similarly, both the fourth back-to-back connected diode R₄ and the fifth back-to-back connected diode R₅ lie on the output side the second operational amplifier 40, and thus it is necessary that the fourth back-to-back connected diode R₄ and the fifth back-to-back connected diode R₅ have the same structure and characteristics.

In conclusion, the low noise amplifier 100 with back-to-back connected diodes in this embodiment has a back-to-back connected diode structure formed from MOS FETs operated within the cut-off region 15 to function as a high-resistance resistor in an amplifier circuit structure; hence, its resistance does not vary greatly with voltage but manifests high stability. Furthermore, it consumes little power, because the back-to-back connected diodes are formed from MOS FETs. The overall circuit structure of the low noise amplifier 100 with back-to-back connected diodes includes less constituent elements than its conventional counterpart, and thus the circuit is not intricate, thereby rendering its manufacturing process easy to control and apply.

The features of the present invention are disclosed above by the preferred embodiment to allow persons skilled in the art to gain insight into the contents of the present invention and implement the present invention accordingly. The preferred embodiment of the present invention should not be interpreted as restrictive of the scope of the present invention. Hence, all equivalent modifications or amendments made to the aforesaid embodiment should fall within the scope of the appended claims.

What is claimed is:

1. A low noise amplifier with back-to-back connected diodes, comprising:
a first operational amplifier having a first input end, a second input end, a first output end, and a second output end; and
at least two first back-to-back connected diodes electrically connected between the first input end and the first output end, and electrically connected between the second input end and the second output end, respectively,
wherein the first back-to-back connected diodes are each formed from at least one MOS FET each operated within a cut-off region.

2. The low noise amplifier of claim 1, wherein the first back-to-back connected diodes are each formed from at least one PMOS FET to form at least one back-to-back P-N-N-P structure, allowing the drain and source thereof to function as two P contacts of the first back-to-back connected diodes, respectively, and allowing the gate to receive a highest voltage.

3. The low noise amplifier of claim 1, wherein the first back-to-back connected diodes are each formed from at least one NMOS FET to form at least one back-to-back N-P-P-N structure, allowing the drain and source thereof to function as two N contacts of the first back-to-back connected diodes, respectively, and allowing the gate to receive a lowest voltage.

4. The low noise amplifier of claim 1, wherein the first input end and the second input end are series-connected to a first capacitor, respectively.

5. The low noise amplifier of claim 1, wherein one of two second capacitors is series-connected between the first input end and the first output end and the other one of two said capacitors is series-connected between the second input end and the second output end.

6. The low noise amplifier of claim 1, further comprising a second operational amplifier including:
a third input end series-connected to a second back-to-back connected diode and then electrically connected to the first output end;
a fourth input end series-connected to a third back-to-back connected diode and then electrically connected to the second output end;
a third output end series-connected to a fourth back-to-back connected diode and then electrically connected to the first input end; and
a fourth output end series-connected to a fifth back-to-back connected diode and then electrically connected to the second input end,
wherein the second back-to-back connected diode, the third back-to-back connected diode, the fourth back-to-back connected diode, and the fifth back-to-back connected diode are each formed from at least one MOS FET each operated within a cut-off region.

7. The low noise amplifier of claim 6, wherein the second back-to-back connected diode, the third back-to-back connected diode, the fourth back-to-back connected diode, or the fifth back-to-back connected diode is formed from at least one PMOS FET to form at least one back-to-back P-N-N-P structure, allowing the drain and source thereof to function as two. P contacts of the second back-to-back connected diode, the third back-to-back connected diode, the fourth back-to-back connected diode, or the fifth back-to-back connected diode correspondingly, and allowing the gate to receive a highest voltage, wherein the second and third back-to-back connected diodes have identical structures, and the fourth and fifth back-to-back connected diodes have identical structures.

8. The low noise amplifier of claim 6, wherein the second back-to-back connected diode, the third back-to-back connected diode, the fourth back-to-back connected diode, or the fifth back-to-back connected. diode is formed from at least one NMOS FET to form at least one back-to-back N-P-P-N structure, allowing the drain and source thereof to function as two N contacts of the second back-to-back connected diode, the third back-to-back connected diode, the fourth back-to-back connected diode, or the fifth back-to-back connected diode correspondingly, and allowing the gate to receive a lowest voltage, wherein the second and third back-to-back connected diodes have identical structures, and the fourth and fifth back-to-back connected diodes have identical structures.

9. The low noise amplifier of claim 6, wherein one of two third capacitors is series-connected between the third input end and the fourth output end and the other one of two said third capacitors is series-connected between the fourth input end and the third output end.

10. A back-to-back connected diode with high impedance, applicable to a low noise amplifier with back-to-back connected diodes, the back-to-back connected diode being formed from at least one MOS FET each operated within a cut-off region.

11. The back-to-back connected diode of claim 10, wherein the back-to-back connected diode is formed from at least one PMOS FET to form at least one back-to-back P-N-N-P structure, allowing the drain and source thereof to function as two P contacts of the back-to-back connected diode, and allowing the gate to receive a highest voltage.

12. The back-to-back connected diode of claim 10, wherein the back-to-back connected diode is formed from at least one NMOS FET to form at least one back-to-back N-P-P-N structure, allowing the drain and source thereof to function as two N contacts of the back-to-back connected diode, and allowing the gate to receive a lowest voltage.
